(19) United States
(12) Patent Application Publication
(10) Pub. No.: US 2009/0056920 A1
(43) Pub. Date: Mar. 5, 2009

(54) Cooling Apparatus and Electronic Device Comprising Same

(76) Inventor: Junsi Lee, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(21) Appl. No.: 12/087,154

(22) PCT Filed: Oct. 3, 2007
(86) PCT No.: PCT/JP2007/069788

§ 371 Date: Aug. 26, 2008

(30) Foreign Application Priority Data
Oct. 5, 2006 (JP) 2006-274277

(51) Int. Cl. F24H 3/02; H05K 7/20

(52) U.S. Cl. 165/121; 361/690; 361/694

(57) ABSTRACT

A cooling apparatus comprises cover 4 equipped with pump body 1, and a housing on which cover 4 is removably mounted. The housing includes a vent forming surface formed with a vent for introducing air into the housing, and a protrusion provided on the vent forming surface so as to surround the vent. Cover 4 includes a communication pipe whose one end fitted into a discharge port of a pressure pump, sheet-type packing 3a which is provided on an another end of said communication pipe and in which an opening at said another end of said communication pipe is positioned in a center portion, and pump fixture 2 for attaching the other end of the communication pipe.

### TECHNICAL FIELD

The present invention relates to a cooling apparatus for cooling down a heat source such as a light source, a CPU and the like.

### BACKGROUND ART

A liquid crystal projector includes a cooling apparatus for cooling down heat sources such as a light source, a liquid crystal panel and the like. Fans are widely employed as the cooling apparatus. However, the fan-based cooling simply feeds air to overall heat sources, and encounters difficulty in achieving a sufficient cooling effect. For achieving a large cooling effect in fan-based cooling, a motor must be rotated at higher speeds to increase air velocity. However, this is not a preferred option because a higher rotational speed of the motor results in an increase in vibrations and operation noise of the motor. Also, in a heat source which locally generates heat such as a light source, it is preferable that the heat generating spot be locally cooled down, but the fan encounters difficulty in performing such local cooling.

Accordingly, there has been proposed a cooling apparatus which is capable of performing local cooling, using a pressure pump (see JP2005-148624A). This cooling apparatus includes a pressure pump (compressor) for taking in and compressing air, an air tank for storing the air that is compressed by the pressure pump, and a cooling nozzle for discharging the air within the air tank. The pressure pump and air tank are coupled through a communication pipe. The cooling nozzle is disposed such that its discharge port is oriented to the desired spot of a heat source. Since the compressed air discharged from the cooling nozzle is fed to the desired spot of the heat source, the heat source is locally cooled down.

### DISCLOSURE OF THE INVENTION

Generally, a pressure pump has a specific lifetime, and the pressure pump must be replaced when its lifetime expires. The cooling apparatus described in JP-2005-148624A has a problem that the replacement of the pressure pump requires significant time and labor because the pump unit is not structured to be removable from the housing.

Also, even if a unit in a replaceable unit structure is used, an air leak can occur at the point of connection between the discharge port of the pressure pump in the unit and the vent of the housing. No proposal has been so far made for a specific approach for preventing the air leak at the connection of the discharge port of the pressure pump with the vent of the housing in the replaceable unit structure.

It is an exemplary object of the present invention to solve each of the problems mentioned above and to provide a cooling apparatus which is capable of restraining an air leak and which can be replaced.

To achieve the above object, a cooling apparatus according to a first invention comprises a pump unit equipped with a pressure pump for discharging compressed air, and a housing in which the pump unit is removably mounted, and is characterized in that the housing includes a vent forming surface in which a vent is formed to introduce air into the housing, and a protrusion formed on the vent forming surface so as to surround the vent, the pump unit includes a communication pipe whose one end is fitted into a discharge port of the pressure pump, a sheet-type packing which is provided on another end of the communication pipe and in which an opening at the another end of the communication pipe is positioned in a center portion, and a pump fixture which is attached to the another end of the communication pipe and includes a pressing surface for pressing the packing against the protrusion, and in a state in which the pump unit is mounted in the housing, the packing is pressed against the protrusion by the pressing surface to join the opening at the another end of the communication pipe to the vent, and a joint portion between the opening and the vent is hermetically sealed by the packing.

A cooling apparatus according to a second invention comprises a pump unit equipped with a pressure pump for discharging compressed air; and a housing in which the pump unit is removably mounted, and is characterized in that the housing includes a vent forming surface in which a vent is formed to introduce air into the housing, the pump unit includes a communication pipe whose one end is fitted into a discharge port of the pressure pump, a sheet-type packing which is provided on another end of the communication pipe and in which an opening at the another end of the communication pipe is positioned in a center portion; and a pump fixture which is attached to the another end of the communication pipe and includes a pressing surface for pressing the packing against the vent forming surface, and in a state in which the pump unit is mounted in the housing, the packing is pressed against the protrusion by the pressing surface to join the opening at the another end of the communication pipe to the vent, and a joint portion between the opening and the vent is hermetically sealed by the packing.

In any of the first and second inventions described above, since the pump unit is structured to be removably mounted in the housing, the pressure pump can be replaced in a simple way when its lifetime has expired.

In addition, since the joint (portion) between the opening at the other end of the communication pipe that is attached to the pressure pump and the vent of the housing is hermetically sealed by the packing, no air leak occurs at the joint.

As described above, according to the present invention, the pressure pump can be replaced in a simple way because of the use of a replaceable pump unit.

In addition, since the joint (portion) between the opening at the other end of the communication pipe that is attached to the pressure pump and the vent of the housing is hermetically sealed by the packing, compressed air from the pressure pump can be efficiently guided to a desired spot within the housing.

The above and other exemplary purposes, features, and advantages of the present invention will become apparent from the following description with reference to the accompanying drawings which illustrate examples of the present invention.

### BRIEF DESCRIPTION OF THE DRAWINGS

FIG. 1 is a perspective view illustrating the structure of a pump unit of a cooling apparatus according to an exemplary embodiment of the present invention;

FIG. 2 is an exploded perspective view of the pump unit illustrated in FIG.

FIG. 3A is a top plan view illustrating how a pump body shown in FIG. 1 is attached to a pump fixture;

FIG. 3B is a cross-sectional view taken along line A-A in FIG. 3A;

FIG. 4 is a perspective view illustrating the configuration of a projector which is equipped with the pump unit illustrated in FIG. 1;

FIG. 5 is a perspective view illustrating the configuration of a body cooling vent forming member shown in FIG. 4;

FIG. 6 is a cross-sectional view illustrating how the pump unit illustrated in FIG. 1 is mounted in a housing;

FIG. 7 is a cross-sectional view illustrating the configuration of a cooling apparatus according to another exemplary embodiment of the present invention; and

FIG. 8 is a perspective view of a projector in which the pump unit illustrated in FIG. 7 is mounted.

### BEST MODE FOR CARRYING OUT THE INVENTION

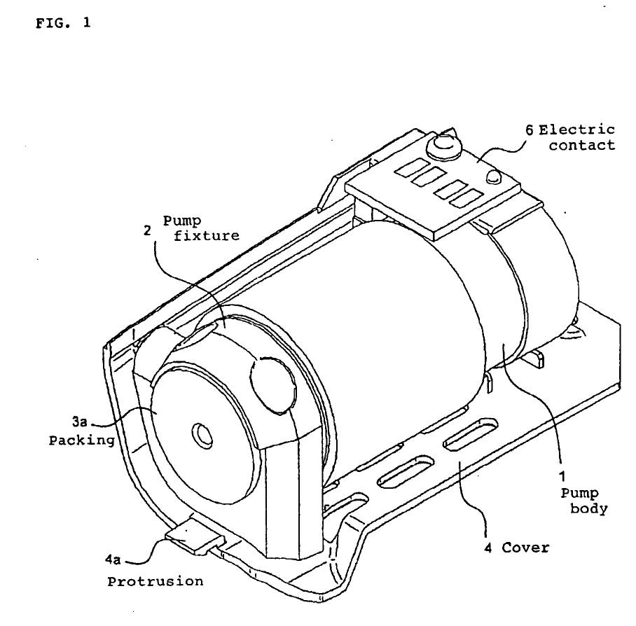

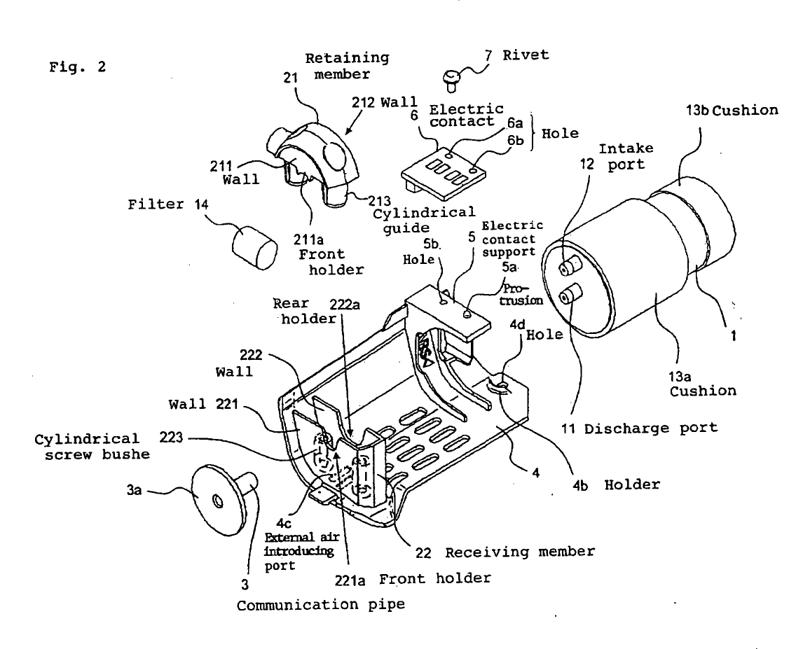

FIG. 1 is a perspective view illustrating the configuration of a pump unit of a cooling apparatus according to an exemplary embodiment of the present invention, and FIG. 2 is an exploded perspective view of the pump unit illustrated in FIG. 1.

Referring to FIGS. 1 and 2, the pump unit is a removable unit which can be mounted in the housing of a projector, and mainly includes pump body 1, pump fixture 2, communication pipe 3, and cover 4.

Pump body 1 takes in air from intake port 12 for compression, and discharges the compressed air from discharge port 11. A cylindrical filter 14 is attached to intake port 12 for preventing debris from being introduced into the pump. Parts of pump body 1, likely to come into contact with other members, are covered with a cushion member. The cushion member is made of an elastic material, for example, sponge-like rubber, synthetic resin or the like, which is capable of absorbing vibrations and shocks. In FIG. 2, the periphery of pump body 1 is covered with cushions 13a, 13b.

Communication pipe 3 is preferably made of an elastic material such as rubber, synthetic resin or the like. One end of communication pipe 3 is fitted into discharge port 11. The other end of communication pipe 3 is provided with discoidal packing 3a. Packing 3a functions to prevent a leak of compressed air fed through communication pipe 3, while the other end of communication pipe 3 is kept pressed against an area of the housing where a vent is provided for connection with communication pipe 3.

Cover 4 includes protrusion 4a for insertion into a hole provided at a predetermined location in a unit chamber of the housing; holder 4b for engagement with a protrusion provided at a predetermined location of the unit chamber; a plurality of external air introducing ports 4c; and hole 4d for screwing cover 4 to the housing. By bringing the protrusion on the housing into engagement with holder 4b, with protrusion 4a inserted into the hole in the housing, a precise mounting position can be determined for the pump unit in the housing. With the pump unit thus positioned, hole 4d is positioned right above a screw hole provided at a predetermined location of the housing, so that a screw is inserted into the screw hole of the housing through this hole 4d, thereby fixing cover 4 to the housing.

Cover 4 is provided on its inner wall with pump fixture 2 for fixing pump body 1, and with electric contact support 5. Electric contact support 5 is provided for mounting electric contact 6 thereon, where protrusion 5a and hole 5b for inserting rivet 5 thereinto are provided on a surface on which electric contact 6 is mounted. Electric contact 6 has a plurality of contacts disposed on a board for connecting pump body 1 with a pump driver, not shown. The substrate is provided with hole 6a into which protrusion 5a is fitted, and hole 6b into which rivet 7 is inserted. By inserting rivets 7 into holes 6b, 5b with protrusion 5a of electric contact support 5 fitted into hole 6a of electric contact 6, electric contact 6 is fixed to electric contact support 5.

Pump fixture 2 includes retaining member 21 and receiving member 22. Receiving member 22, which has a “U” shaped cross section, includes front wall 221 (at which the vent of the housing is positioned when the unit is mounted): rear wall 222 (at which pump body 1 is positioned): and cylindrical screw bushes 223 provided between these walls for fixedly screwing retaining member 21. Walls 221, 222 are formed with front hold er 221a and rear holder 222a, respectively, at upper ends thereof. Front holder 221a and rear holder 222a are cut into parts of the walls in U-shape.

Retaining member 21 includes front wall 211, the lower end of which matches with the upper end of wall 221; and rear wall 212, the lower end of which matches with the upper end of wall 222, and is provided with cylindrical guides 213 between these walls 211, 212 for guiding screws when they are screwed into screw bushes 223. Walls 211, 212 are formed with front holder 211a and a rear holder (not shown), respectively, at lower ends thereof. These front holder 211a and rear holder are cut into parts of the walls in U-shape.

With retaining member 21 screwed to receiving member 22, a uniform surface is defined by wall 211 of retaining member 21 and wall 221 of receiving member 22. An opening is formed in part of the surface by front holder 211a of wall 211 and front holder 221a of wall 221. This opening has a diameter smaller than the outer diameter of communication pipe 221, thereby making it possible to fix part of communication pipe 2 with the opening. Similarly, with retaining member 21 screwed to receiving member 22, a uniform surface is defined by wall 212 of retaining member 21 and by wall 222 of receiving member 22, and an opening is formed in part of the surface by the rear holder of wall 212 and rear holder 222a of wall 222. A space formed by this opening is sufficiently large so that discharge port 11 and intake port 12 of pump body 1 can be inserted thereinto. Discharge port 11 and intake port 12 of pump body 1 do not come into contact with the rear holder of wall 212 and rear holder 222a of wall 222.

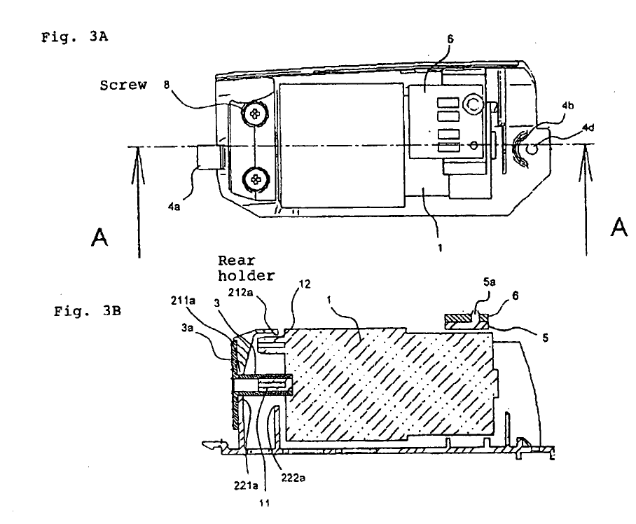

FIG. 3A is a top plan view for describing how pump body 1 is fixed by pump fixture 2, and FIG. 3B is a cross-sectional view taken along line A-A in FIG. 3A.

As illustrated in FIG. 3A, retaining member 21 is screwed to receiving member 22 with screw 8. As illustrated in FIG. 3B, one end of communication pipe 3 is fitted into discharge port 11 of pump body 1, and part of this communication pipe 3 (here, a portion provided with packing 3a), except for the one end fitted into discharge port 11, is fixed by front holder 221a of wall 211 and front holder 221a of wall 221. Packing 3a is disposed over the uniform surface defined by walls 211, 221. When the unit is mounted, packing 3a prevents the leak of compressed air fed through communication pipe 3. Discharge port 11 and intake port 12 of pump body 1 are disposed within the opening formed by rear holder 212a of wall 212 and rear holder 222a of wall 222.

Next, a description will be given of a structure for mounting the pump unit in a projector.

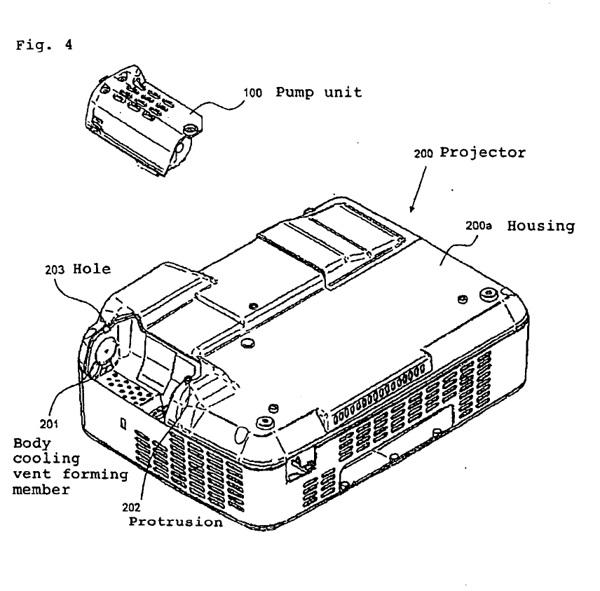

FIG. 4 is a perspective view illustrating the configuration of a projector which is equipped with the pump unit illustrated in FIG. 1. Referring to FIG. 4, projector 200 includes housing 200a which contains a light source, a liquid crystal panel, an illumination optical system for irradiating the liquid crystal panel with light from the light source, and the like; and removable pump unit 100 mounted in housing 200a. Pump unit 100 is the pump unit illustrated in FIG. 1.

A portion of housing 200a in which pump unit 100 is mounted is formed with body cooling vent forming member 201 against which packing 3a of communication pipe 3 is pressed; protrusion 202 for engagement with holder 4b of cover 4; and hole 203 for inserting protrusion 4a of cover 4 thereinto.

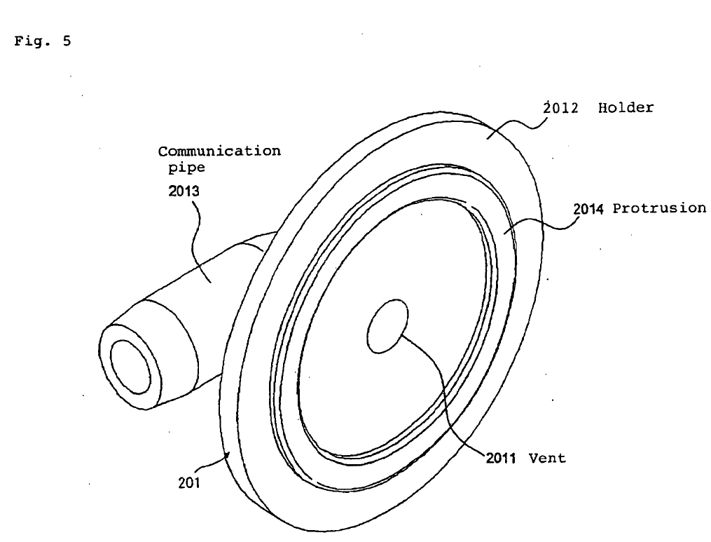

As illustrated in FIG. 5, body cooling vent forming member 201 includes planar holder 2012 formed with vent 2011 at the center thereof; and communication pipe 2013 for coupling vent 2011 to a pipe within housing 200a (communication pipe for leading compressed air discharged from pump body 1 to a heat source). Body cooling vent forming member 201 is attached to a wall into which protrusion 4a of cover 4 is inserted.

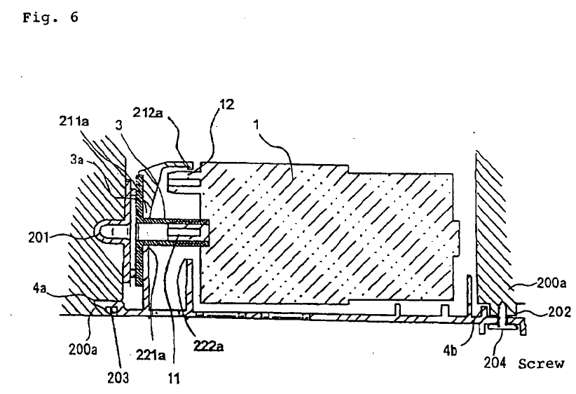

FIG. 6 illustrates the structure in cross-sectional view when pump unit 100 is mounted in housing 200a. As illustrated in FIG. 6, protrusion 4a of pump unit 100 is inserted into hole 203 of housing 200a, and holder 4b of pump unit 100 is brought into engagement with protrusion 202 of housing 200a, thereby positioning pump unit 100 with respect to housing 200a. With pump unit 100 thus positioned, hole 4a is positioned right above the screw hole provided in protrusion 202 of housing 200a. By inserting screw 204 into the screw hole of housing 200a through hole 4d, pump unit 100 is fixed to housing 200a.

With pump unit 100 fixed to housing 200a, packing 3a of communication pipe 3 is pressed against holder 2012 of body cooling vent forming member 201 by the surface defined by front walls 211, 221 with an appropriate force. As a result, the discharge port at one end of communication pipe 3 is in communication with vent 2011 of holder 2012, so that air at high static pressure, discharged from discharge port 11 of pump body 1, is fed from vent 2011 to the pipe within housing 200a. A heat source such as a light source is disposed beyond the outlet of the pipe, so that the desired part of the heat source can be cooled down by the compressed air from pump body 1.

A force for pressing packing 3 against holder 2012 is uniform over the entire surface. For generating the force for pressing packing 3a against protrusion 2014 of holder 2012, spacing D between the surface formed by front walls 211, 221 (pressing surface) and holder 2012 of body cooling vent forming member 201 (vent forming surface) is smaller than the total of thickness T1 of packing 3a and thickness T2 of protrusion 2014 when pump unit 100 remains fixed to housing 200a. The size of spacing D to thickness (T1+T2) dominates the force for pressing packing 3a against holder 2012. As the value of ([T1+T2]−D) is larger, packing 3a is pressed against protrusion 2014 with a larger force, which results in a higher effect for preventing the leakage of air.

Also, the pressing surface is substantially parallel with the vent forming surface when pump unit 100 remains fixed to housing 200a. In this way, packing 3a can be pressed against overall protrusion 2014 with a uniform force.

Further, guide 213 and screw base 223 are disposed behind walls 211, 221 (on the side opposite to the side on which packing 3a is disposed) to increase the rigidity of the surface defined by walls 211, 221. Consequently, packing 3a can be pressed against protrusion 2014 of holder 2012 with an uniform force.

Further, protrusion 2014 is preferably provided at a position which is opposite a portion of the surface defined by walls 211, 221 which has a higher rigidity. Specifically, protrusion 2014 is preferably provided at a position which is opposite a region in which guide 213 and screw base 223 are disposed. In this way, when packing 3a is pressed against protrusion 2014 by the surface defined by walls 211, 221, a portion of the surface which exhibits a higher rigidity will cause packing 3a to be depressed. In this connection, if the rigidity of the surface is low, it is difficult to press packing 3a against protrusion 2014 with a uniform force, possibly causing an air leak.

According to the cooling apparatus of the embodiment described above, since the pump unit is structured to be removably mounted in the housing, a pressure pump can be replaced in a simple way when its lifetime has expired.

In addition, since the joint between the opening at the other end of the communication pipe that is attached to the pressure pump and the vent of the housing is hermetically sealed by the packing, no air will leak from the joint. Accordingly, the compressed air from the pressure pump can be efficiently guided to a desired spot within the housing.

### ANOTHER EXEMPLARY EMBODIMENT

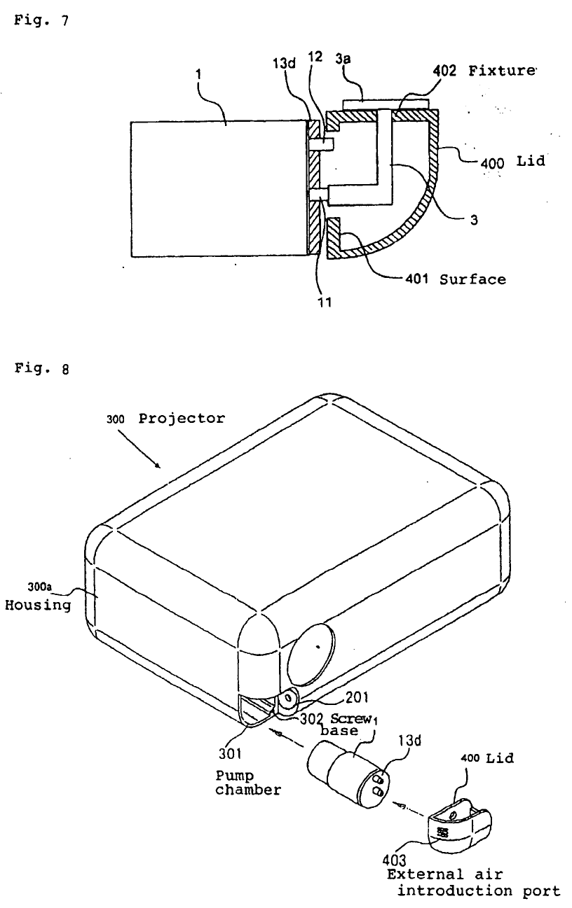

FIG. 7 is a cross-sectional view illustrating the configuration of a pump unit of a cooling apparatus according to another exemplary embodiment of the present invention, and FIG. 8 is a perspective view of a projector in which the pump unit illustrated in FIG. 7 is mounted.

Referring to FIGS. 7 and 8, the pump unit is a removable unit mounted in housing 300a of projector 300, and mainly includes pump body 1, lid 400 including a pump fixing structure, and communication pipe 3. Pump body 1 and communication pipe 3 are similar to those shown in FIG. 1. One end of communication pipe 3 is fitted into discharge port 11. Cushion 13d is applied over a surface of pump body 1 on which discharge port 11 and intake port 12 are provided. A discoidal packing 3a is provided at the other end of communication pipe 3.

Housing 300a is provided with pump chamber 301 for mounting pump body 1 therein, and body cooling vent forming member 201 is provided near an open end of pump chamber 301. Screw base 302 is provided at the open end of pump chamber 301 for attaching lid 400. Body cooling vent forming member 201 is the same as that shown in FIG. 5.

Lid 400 includes surface 401 formed with an opening; fixture 402 for attaching part of communication pipe 3 (part of communication pipe 3 except for a joint with discharge port 11); and external air introduction port 403. Packing 3a is disposed on the outer surface of a wall on which fixture 402 is formed (pressing surface). A space defined by the opening formed through surface 401 is sufficiently large so that discharge port 11 and intake port 12 of pump body 1 can be inserted therein. Discharge port 11 and intake port 12 of pump body 1 do not come into contact with the end of the opening.

Though not shown, pump chamber 301 and lid 400 are also provided with positioning means for precisely determining the position at which lid 400 is attached, such as a protrusion, a holder for receiving the protrusion, and the like. Further, lid 400 is provided with a screwing hole for inserting a screw into screw base 302 in the positioned state.

As illustrated in FIG. 8, in the projector of this embodiment, pump body 1 is inserted into pump chamber 301, and lid 400 is screwed to an open end of pump receiver 301. With lid 400 attached by a screw, packing 3a is pressed against protrusion 2014 of holder 2012 of body cooling vent forming member 201 by the outer surface of the wall on which fixture 402 is formed. As a result, communication pipe 3 is in communication with vent 2011 of holder 2012, so that air at high static pressure discharged from discharge port 11 of pump body 1 is fed from vent 2011 to a pipe within housing 300a. Packing 3a is pressed against holder 2012 with a uniform force over the entire surface. A heat source such as a light source is disposed beyond the outlet of the pipe, and a desired spot of the heat source can be cooled down by the compressed air from pump body 1.

Alternatively, fixture 402 may be in a separate structure like pump fixture 2 shown in FIG. 1. The separate structure includes a pressing member including a first concave holder conforming to the outside shape of communication pipe 3; a receiving member including a second concave holder conforming to the outside shape of communication pipe 3; and fixing means (a screwing mechanism, a fixing mechanism employing a pawl and an engaging part to which the pawl is engaged, or the like) for fixing the retaining member to the receiving member. With the employment of the separate structure, fixture 402 can be reused, thus leading to a lower manufacturing.

The cooling apparatus of each embodiment described above is an exemplary example of the present invention, and can be modified in configuration as appropriate without departing from the essence of the present invention. For example, protrusion 2014 may not be provided to body cooling vent forming member 201 in which the leakage o are can only be prevented only by the packing at the joint which connects the communication pipe and the vent.

Also, another protrusion may be provided inside of a region of the pressing surface opposite to the protrusion, with the pump unit mounted in the housing, so as to surround the opening at the other end of the communication pipe.

Also, another protrusion may be provided outside of the region of the pressing surface opposite to the protrusion, with the pump unit mounted in the housing, so as to surround the opening at the other end of the communication pipe.

Also, the vent forming member formed with the vent forming surface may be formed integrally with the housing.

The cooling apparatus of the present invention can be generally applied to electronic devices such as information processing apparatuses represented by a personal computer, display devices represented by a liquid crystal display device and a plasma display, and the like. In an electronic device which employs the cooling apparatus of the present invention, a control unit represented by a CPU, an operating unit controlled by this control unit are contained in a housing in which the pump unit is removably mounted, to locally cool down a desired spot, such as the control unit, with compressed air from the pressure pump.

This application is based upon and claims the benefit of priority from Japanese Patent Application No. 2006-274277 filed in Japan Patent Office on Oct. 5, 2006, the contents of which are hereby incorporated by reference.

While exemplary embodiments of the present invention have been described using specific terms, such description is for illustrative purposes only, and it is to be understood that changes and variations may be made without departing from the spirit or scope of the following claims.

1. A cooling apparatus comprising:
a pump unit equipped with a pressure pump for discharging compressed air; and
a housing in which said pump unit is removably mounted,
wherein said housing includes:
a vent forming surface in which a vent is formed to introduce air into said housing; and
a protrusion formed on said vent forming surface so as to surround said vent,
said pump unit includes:
a communication pipe whose one end is fitted into a discharge port of said pressure pump;
a sheet-type packing which is provided on another end of said communication pipe and in which an opening at said another end of said communication pipe is positioned in a center portion; and
a pump fixture which is attached to said another end of said communication pipe and includes a pressing surface for pressing said packing against said protrusion, and
in a state in which said pump unit is mounted in said housing, said packing is pressed against said protrusion by said pressing surface to join the opening at said another end of said communication pipe to said vent, and a joint portion between the opening and said vent is hermetically sealed by said packing.

2. The cooling apparatus according to claim 1, further comprising another protrusion which is provided inside of a region on said pressing surface that is opposite to said protrusion in the state in which said pump unit is mounted in said housing, so as to surround the opening at said another end of said communication pipe.

3. The cooling apparatus according to claim 1, further comprising another protrusion provided outside of a region on said pressing surface that is opposite to said protrusion in the state in which said pump unit is mounted in said housing, so as to surround the opening at said another end of said communication pipe.

4. The cooling apparatus according to claim 1, further comprising a vent forming member in which said vent forming surface is formed, wherein said vent forming member is configured to be removable from said housing.

5. The cooling apparatus according to claim 1, wherein:
said pump fixture includes a reinforcement member on a surface opposite to said pressing surface for increasing a rigidity of said pressing surface, and
said protrusion is formed at a position corresponding to a location of said pressing surface at which said reinforcement member is disposed.

6. A cooling apparatus comprising:
a pump unit equipped with a pressure pump for discharging compressed air; and
a housing in which said pump unit is removably mounted,
wherein said housing includes a vent forming surface in which a vent is formed to introduce air into said housing
said pump unit includes:
a communication pipe whose one end is fitted into a discharge port of said pressure pump;
a sheet-type packing which is provided on another end of said communication pipe and in which an opening at said another end of said communication pipe is positioned in a center portion; and
a pump fixture which is attached to said another end of said communication pipe and includes a pressing surface for pressing said packing against said vent forming surface, and
in a state in which said pump unit is mounted in said housing, said packing is pressed against said protrusion by said pressing surface to join the opening at said another end of said communication pipe to said vent, and a joint portion between the opening and said vent is hermetically sealed by said packing.

7. An electronic device comprising:
a pump unit equipped with a pressure pump for discharging compressed air; and
a housing for containing a control unit and an operation unit operated under the control of said control unit, said pump unit being removably mounted in said housing,
wherein said housing includes:
a vent forming surface in which a vent is formed to introduce air into said housing; and
a protrusion formed on said vent forming surface so as to surround said vent,
said pump unit includes:
a communication pipe whose one end is fitted into a discharge port of said pressure pump;
a sheet-type packing which is provided on another end of said communication pipe and in which an opening at said another end of said communication pipe is positioned in a center portion; and
a pump fixture which is attached to said another end of said communication pipe and includes a pressing surface for pressing said packing against said protrusion, and
in a state in which said pump unit is mounted in said housing, said packing is pressed against said protrusion by said pressing surface to join the opening at said another end of said communication pipe to said vent, and a joint portion between the opening and said vent is hermetically sealed by said packing.

8. An electronic device comprising:
a pump unit equipped with a pressure pump for discharging compressed air; and
a housing for containing a control unit and an operation unit operated under the control of said control unit, said pump unit being removably mounted in said housing,
wherein said housing includes a vent forming surface in which a vent is formed to introduce air into said housing
said pump unit includes:
a communication pipe whose one end is fitted into a discharge port of said pressure pump;
a sheet-type packing which is provided on another end of said communication pipe and in which an opening at said another end of said communication pipe is positioned in a center portion; and
a pump fixture which is attached to said another end of said communication pipe and includes a pressing surface for pressing said packing against said vent forming surface, and
in a state in which said pump unit is mounted in said housing, said packing is pressed against said protrusion by said pressing surface to join the opening at said another end of said communication pipe to said vent, and a joint portion between the opening and said vent is hermetically sealed by said packing.

9. A cooling apparatus comprising:
a pump unit equipped with a pressure pump for discharging compressed air; and
a housing in which said pump unit is removably mounted,
wherein said housing includes:
a vent forming surface in which a vent is formed to introduce air into said housing; and
a protrusion formed on said vent forming surface so as to surround said vent,
said pump unit includes:
a communication pipe whose one end is fitted into a discharge port of said pressure pump;
a sheet-type packing which is provided on another end of said communication pipe and in which an opening at said another end of said communication pipe is positioned in a center portion; and
pump fitting means for fitting said another end of said communication pipe to said pump unit, and
in a state in which said pump unit is mounted in said housing, said packing is pressed against said protrusion by said pump fitting means to join the opening at said another end of said communication pipe to said vent, and a joint portion between the opening and said vent is hermetically sealed by said packing.

10. A cooling apparatus comprising:
a pump unit equipped with a pressure pump for discharging compressed air; and
a housing in which said pump unit is removably mounted,
wherein said housing includes a vent forming surface in which a vent is formed to introduce air into said housing
said pump unit includes:
a communication pipe whose one end is fitted into a discharge port of said pressure pump;
a sheet-type packing which is provided on another end of said communication pipe and in which an opening at said another end of said communication pipe is positioned in a center portion; and
pump fitting means for fitting said another end of said communication pipe to said pump unit, and
in a state in which said pump unit is mounted in said housing, said packing is pressed against said protrusion by pump fitting means to join the opening at said another end of said communication pipe to said vent, and a joint portion between the opening and said vent is hermetically sealed by said packing.
